(19) United States
(12) Patent Application Publication
(10) Pub. No.: US 2019/0075679 A1
(43) Pub. Date: Mar. 7, 2019

(54) POWER SUPPLY MODULE WITH ENHANCED HEAT DISSIPATION EFFECT

(71) Applicant: ZIPPY TECHNOLOGY CORP., New Taipei (TW)

(72) Inventors: Chin-Wen CHOU, New Taipei (TW); Yung-Hsin HUANG, New Taipei (TW); Yu-Yuan CHANG, New Taipei (TW); Chun-Lung SU, New Taipei (TW); Yung-Feng CHIU, New Taipei (TW); Chih-Hao CHEN, New Taipei (TW)

(21) Appl. No.: 15/696,852

(22) Filed: Sep. 6, 2017

(51) Int. Cl. H05K 7/20; H05K 5/02; H05K 7/18

(52) U.S. Cl. CPC H05K 7/20136; H05K 7/18; H05K 5/023; H05K 5/0247

(57) ABSTRACT

A power supply module with enhanced heat dissipation effect includes a rack including an opening and an accommodating room connected to the opening, as well as at least one power supply including a fitting section inserted from the opening while positioned within the accommodating room, and a heat dissipation section extending toward the outside of the opening from the opening, in which the power supply is formed in the heat dissipation section with a plurality of heat dissipation holes, in such a way that air is capable of entering the power supply from an output end to form heat convection together with the dissipation holes, so as to form a heat dissipation effect with respect to the power supply.

### FIELD OF THE INVENTION

The present invention is related to a power supply module, particularly to a power supply module with enhanced heat dissipation effect.

### BACKGROUND OF THE INVENTION

In respect of a power supply module, Taiwan Patent No. 1536711, which was filed by the applicant previously, disclosed a “redundant power supply module” including a case, an integrated power backplate, a plurality of power supply modules and a power modulation module. The case is provided with a mounting room defining a first mounting region and a second mounting region. The integrated power backplate is provided in the mounting room. The power supply modules are provided in the first mounting region and connected to the integrated power backplate. The power modulation module is provided in the second mounting region and connected to the integrated power backplate. Each of the power supply modules is allowed to output working power toward the integrated power backplate after being started up. The working power is obtained by the power modulation module from the integrated power backplate, and modulated to generate an auxiliary working power to be outputted to the integrated power backplate. The integrated power backplate is allowed to provide the working power and the auxiliary working power to an external device. Thereby, maintenance of the modular redundant power supply is simplified, and an engineer is further allowed to select the required power modulation module depending on the actual need due to the modular design. As illustrated in FIG. 1, the power supply 20a is enclosed in the case 10a wholly. Therefore, for the enhancement of the heat dissipation effect of the power supply 20a, the power supply 20a is provided at the front end thereof with a heat dissipation fan 50a, through which heat energy due to operation within the power supply 20a may be rejected outward.

For solving the problem of heat dissipation of the power supply, U.S. Pat. No. 6,246,580 disclosed a “power supply for computer system” provided with at least one power supply in a rack, which encloses the power supply wholly, only leaving a handgrip protruded at the outside of the rack. In this way, the heat energy generated when the power supply is operated, is only rejected through a plurality of heat dissipation holes provided at front.

As illustrated in FIG. 2, there is shown a power supply 20b provided at the front thereof with a plurality of heat dissipation holes 21b. It is primary for the power supply 20b to be provided with the plurality of heat dissipation holes 21b at front. The object of heat dissipation is achieved by rejecting heat energy generated within the power supply 20b outward through the heat dissipation holes 21b when at least one heat dissipation fan 50b provided in the power supply 20b is operated. However, the area reserved for the heat dissipation holes 21b is restricted, because it is necessary to reserve an area for an electrical connector 40b to be electrically coupled to an external power source at the front of the power supply 20b.

The space within the power supply 20b is narrowed considerably, however, owing to elements including a rectifying/filtering unit, power calibration unit, secondary rectifying/filtering unit, transformer, pulse width control unit, and etc., generally provided in the power supply 20b. An air stream, generated when the heat dissipation fan 50b is operated, could not be successfully rejected outward through the heat dissipation holes 21b directly after passing through the elements, and part of heat energy is then accumulated behind the electrical connector 40b. The heat energy accumulated over a long period of time is apt to cause damage of the electrical connector 40b, and even further apt to cause burnout of the electrical connector 40b.

Furthermore, as disclosed in U.S. Patent Application Publication No. 2017027073 and Taiwan Published Patent No. 201208550, the rack may be cuttingly provided thereon with a plurality of heat dissipation holes for the enhancement of the heat dissipation effect of the power supply, so as to enhance the heat dissipation effect of the whole power supply module. However, the power supply is provided in the rack, and thus, the heat dissipation holes provided on the rack are not conducive to air entering the power supply directly for generating the effect of heat convection and bring out heat energy directly, with limited improvement on the heat dissipation effect of the power supply.

### SUMMARY OF THE INVENTION

In light of the above, it is the main object of the present invention to provide a power supply module with enhanced heat dissipation effect.

In accordance with the above object, the present invention provides a power supply module with enhanced heat dissipation effect including a rack and at least one power supply. The rack is provided with an opening and an accommodating room connected to the opening. The power supply is provided with an input end being located at the outside of the opening of the rack to be connected to an external power source and including a plurality of front heat dissipation holes, an output end located in the accommodating room to be connected to an integrated power backplate, and a main body portion connected between the input end and the output end. The main body portion is separated as a fitting section inserted from the opening while positioned within the accommodating room and connected to the output end, as well as a heat dissipation section extending toward the outside of the opening from the opening while connected between the fitting section and the input end. In this case, the main body portion includes a top plate provided in the heat dissipation section with a plurality of upper heat dissipation holes, a bottom plate opposite to and spaced with respect to the top plate as well as provided in the heat dissipation section with a plurality of lower heat dissipation holes, and two side plates respectively located at two sides of the top plate and the bottom plate so as to connect the top plate and the bottom plate, each of the side plates being provided in the heat dissipation section with a plurality of side heat dissipation holes, in such a way that air is capable of entering the power supply from the output end to form heat convection together with the plurality of upper heat dissipation holes, the plurality of lower heat dissipation holes, the plurality of side heat dissipation holes and the plurality of front heat dissipation holes, so as to form a heat dissipation effect with respect to the power supply.

In one embodiment, each of the side plates is further composed of an upper side plate connected to the top plate and a lower side plate connected to the bottom plate, as well as the plurality of side heat dissipation holes are distributed over the upper side plate and the lower side plate.

In one embodiment, the input end further includes an electrical connector to be electrically coupled to an external power source.

In one embodiment, the input end is further provided with a handgrip to be grasped for facilitating a swap of the power supply with respect to the rack.

In one embodiment, the power supply further includes a heat dissipation fan provided in the main body portion for introducing the air from the output end and guiding the air toward the heat dissipation section.

In comparison with existing technology, it is substantially for the present invention to effectively achieve, via the above technical solution, advantageous effects as follows.

It is primary for the present invention to utilize the heat dissipation section, provided with the plurality of upper heat dissipation holes, the plurality of lower heat dissipation holes and the plurality of side heat dissipation holes, of the power supply, in such a way that the heat dissipation section is protrudingly provided at the outside of the opening of the rack, so as to enable the air entering the power supply from the output end and then forming heat convection together with the plurality of upper heat dissipation holes, the plurality of lower heat dissipation holes, the plurality of side heat dissipation holes and the plurality of front heat dissipation holes. Thereby, a heat dissipation effect with respect to the power supply is formed, such that an enhanced heat dissipation effect is provided for the power supply module of the present invention.

### BRIEF DESCRIPTION OF THE DRAWINGS

FIG. 1 is a diagram of a conventional power supply module.

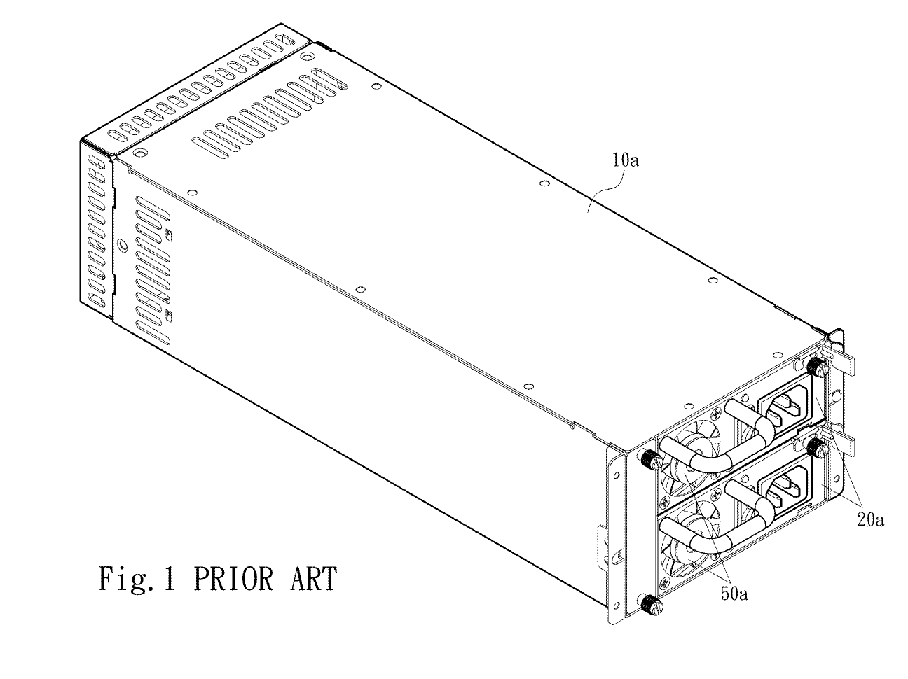

FIG. 2 is a diagram of another conventional power supply.

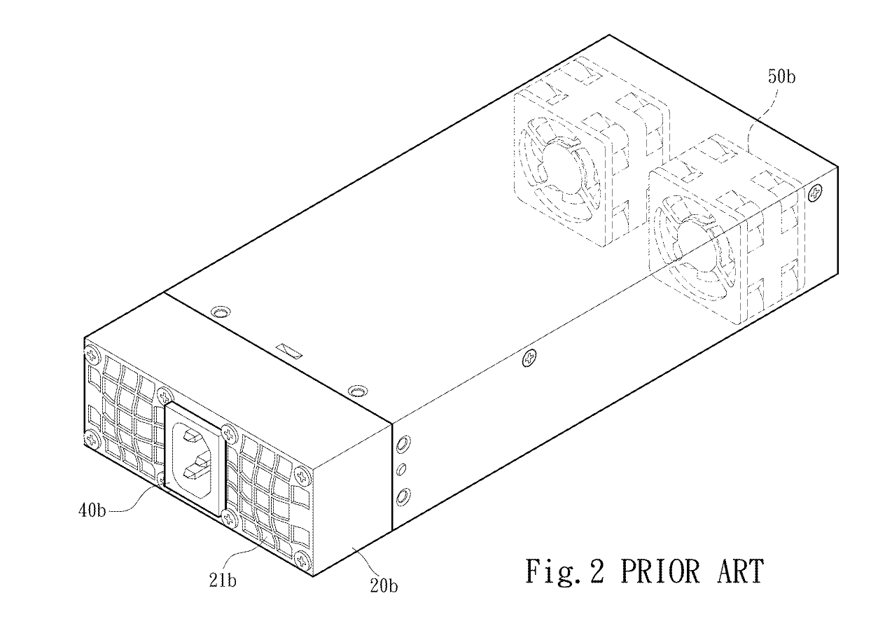

FIG. 3 is a perspective diagram of the present invention.

FIG. 4 is an exploded diagram of the present invention.

FIG. 5 is a perspective diagram of the present invention at another view angle.

FIG. 6 is a side plan view of the present invention.

FIG. 7 is a diagram showing the path of air stream passing through the power supply of the present invention.

### DETAILED DESCRIPTION OF THE PREFERRED EMBODIMENTS

The detailed description and technical content related to the present invention is described in accompany with the drawings as follows.

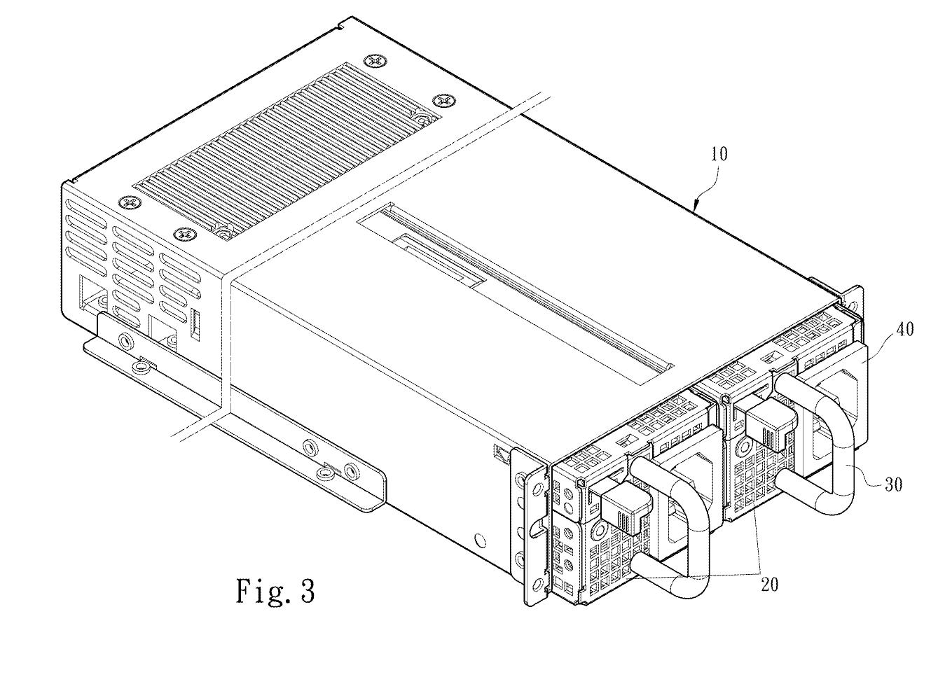

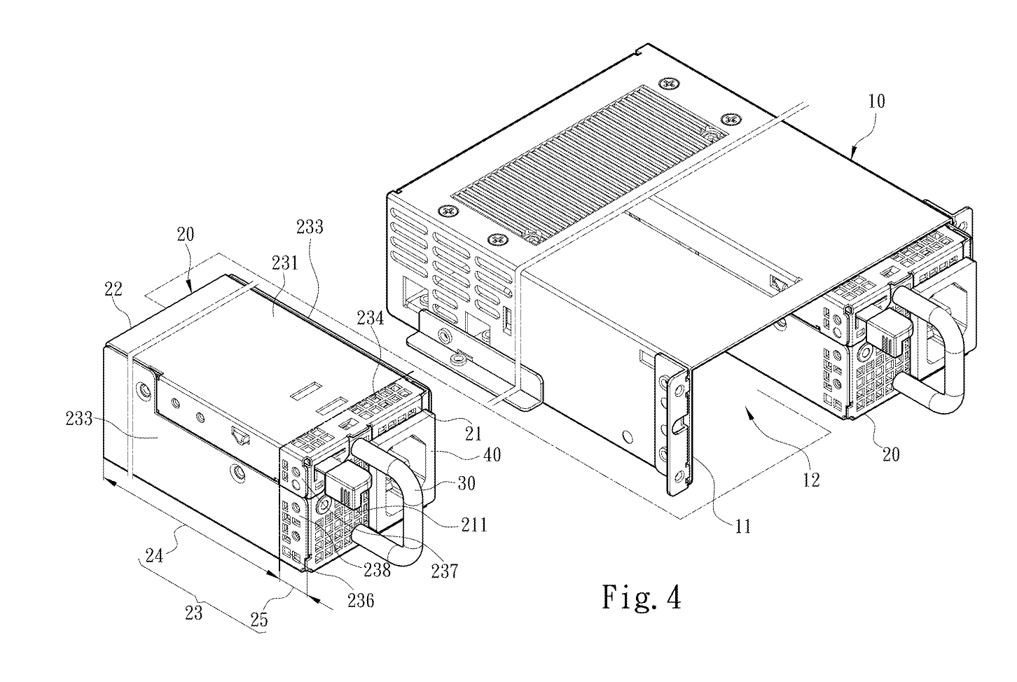

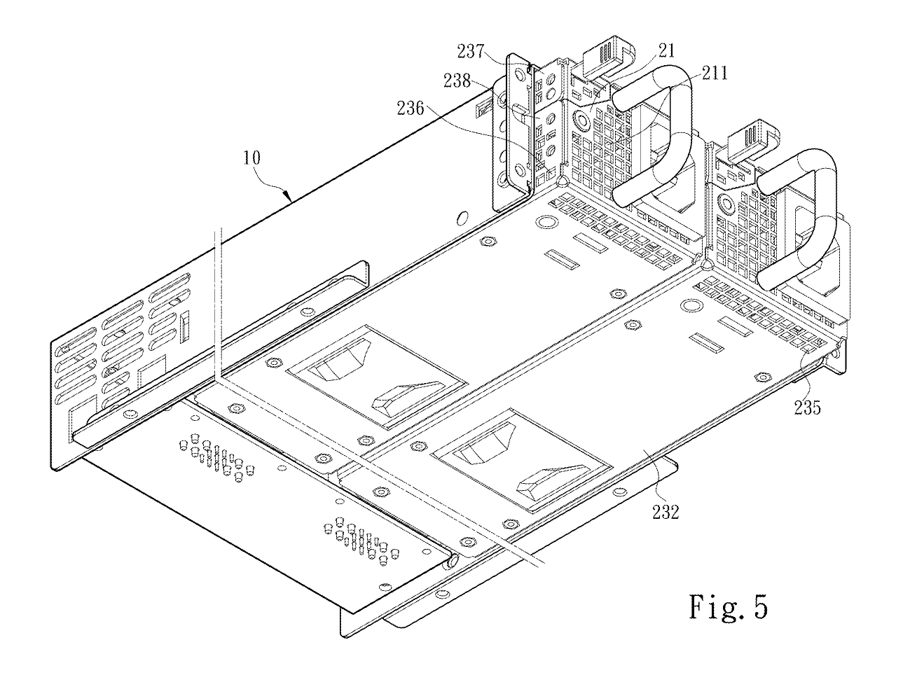

Referring to FIGS. 3, FIG. 4 and FIG. 5, there is a redundant power supply module with enhanced heat dissipation effect, particularly the one including a rack 10 and at least one power supply 20, proposed by the present invention.

The rack 10 is provided thereon with an opening 11, as well as an accommodating room 12 being connected to and extending from the opening 11. In this embodiment, the rack 10 provided therein with two power supplies 20 is considered as a main pattern of embodiment. In the practical application, however, the rack 10 may be also provided therein with the power supply 20, or with two or more power supplies 20 simultaneously.

The power supply 20 is provided with an input end 21, an output end 22, and a main body portion 23 connected between the input end 21 and the output end 22. The input end 21, located at the outside of the opening 11 of the rack 10, is provided thereon with a handgrip 30 to be grasped for facilitating a swap of the power supply 20 with respect to the rack 10 and a power connector 40 to be connected to an external power source (belonging to the conventional technology without described further and shown in the figures). The output end 22 is located at the other side, opposite to the opening 11, of the accommodating room 12, and is connected to an integrated power backplate (belonging to the conventional technology without described further and shown in the figures) within the accommodating room 12. The main body portion 23 is separated as a fitting section 24 inserted from the opening 11 while positioned within the accommodating room 12 and connected to the output end 22, as well as a heat dissipation section 25 extending toward the outside of the opening 11 from the opening 11 while connected between the fitting section 24 and the input end 21.

In this embodiment, the main body portion 23 includes a top plate 231, a bottom plate 232 opposite to and spaced with respect to the top plate 231, and two side plates 233 respectively located at two sides of the top plate 231 and the bottom plate 232 so as to connect the top plate 231 and the bottom plate 232. The top plate 231 is provided at the location of the heat dissipation section 25 with a plurality of upper heat dissipation holes 234, the bottom plate 232 is provided at the location of the heat dissipation section 25 with a plurality of lower heat dissipation holes 235, each of the side plates 233 is provided at the location of the heat dissipation section 25 with a plurality of side heat dissipation holes 236, and the input end 21 is provided thereon with a plurality of front heat dissipation holes 211.

In this embodiment, moreover, each of the side plates 233 is further composed of an upper side plate 237 and a lower side plate 238. Each of the upper side plates 237 and the top plate 231 are connected to each other, each of the lower side plates 238 and the bottom plate 232 are connected to each other. In addition, the plurality of side heat dissipation holes 236 on each of the side plates 233 are distributed over the upper side plate 237 and the lower side plate 238.

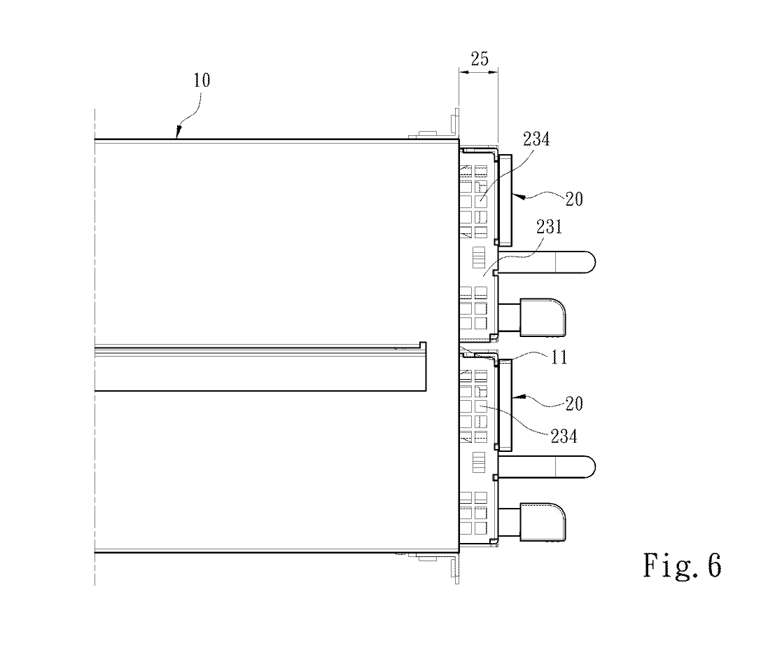

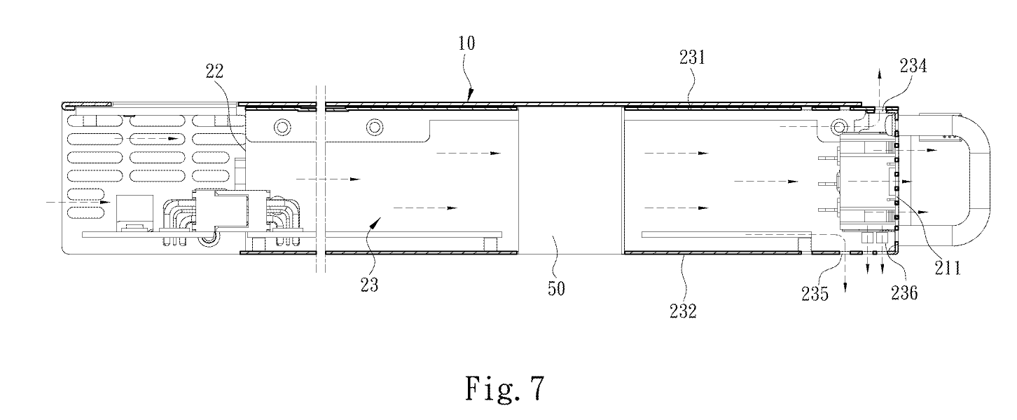

As illustrated in FIG. 6 and FIG. 7, the heat dissipation section 25 of the power supply 20 is protruded at the outside of the opening 11 of the rack 10. Therefore, the plurality of upper heat dissipation holes 234, the plurality of lower heat dissipation holes 235, the plurality of side heat dissipation holes 236 and the plurality of front heat dissipation holes 211 are similarly protrudingly provided at the outside of the opening 11 along with the heat dissipation section 25.

Accordingly, in the practical application of the power supply module, it is capable of introducing air through the output end 22, enabling the air to pass through the main body portion 23 and then form heat convection via the plurality of upper heat dissipation holes 234, the plurality of lower heat dissipation holes 235, the plurality of side heat dissipation holes 236 and the plurality of front heat dissipation holes 211. Further, heat energy, generated when the power supply 20 is operated, may be prevented from being accumulated within the power supply 20.

In this embodiment, at least one heat dissipation fan 50 may be further provided in the power supply 20 for increasing flow velocity of air stream within the power supply 20. In this case, the heat dissipation fan 50 is used to introduce the air from the output end 22, so as to guide heat energy, generated when the power supply 20 is operated, to the heat dissipation section 25 through the air, and then enable the heat energy to pass through the plurality of upper heat dissipation holes 234, the plurality of lower heat dissipation holes 235, the plurality of side heat dissipation holes 236 and the plurality of front heat dissipation holes 211 through the air so as to form heat convection. Further, the heat energy is prevented from being accumulated within the power supply 20, so as to avoid breakdown or burnout of the power supply 20 due to excessively high temperature.

In the practical application, it is also possible to provide the heat dissipation fan 50 at the outside of the output end 22 of the power supply 20, and it is similarly capable of guiding the air to the interior of the power supply 20 from the output end 22 via the heat dissipation fan 50.

In comparison with the prior technology, it is primary for the present invention to utilize the heat dissipation section 25, provided with the plurality of upper heat dissipation holes 234, the plurality of lower heat dissipation holes 235 and the plurality of side heat dissipation holes 236, of the power supply 20, in such a way that the heat dissipation section 25 is protrudingly provided at the outside of the opening 11 of the rack 10, so as to enable the air entering the power supply 20 from the output end 22 and then forming heat convection together with the plurality of upper heat dissipation holes 234, the plurality of lower heat dissipation holes 235, the plurality of side heat dissipation holes 236 and the plurality of front heat dissipation holes 211. Thereby, a heat dissipation effect with respect to the power supply 20 is formed, such that an enhanced heat dissipation effect is provided for the power supply module of the present invention.

What is claimed is:

1. A power supply module with enhanced heat dissipation effect, comprising:
a rack, provided with an opening and an accommodating room connected to said opening; and
at least one power supply, provided with an input end being located at the outside of said opening of said rack to be connected to an external power source and including a plurality of front heat dissipation holes, an output end located in said accommodating room to be connected to an integrated power backplate, and a main body portion connected between said input end and said output end, said main body portion being separated as a fitting section inserted from said opening while positioned within said accommodating room and connected to said output end, as well as a heat dissipation section extending toward the outside of said opening from said opening while connected between said fitting section and said input end, in which said main body portion includes a top plate provided in said heat dissipation section with a plurality of upper heat dissipation holes, a bottom plate opposite to and spaced with respect to said top plate as well as provided in said heat dissipation section with a plurality of lower heat dissipation holes, and two side plates respectively located at two sides of said top plate and said bottom plate so as to connect said top plate and said bottom plate, each of said side plates being provided in said heat dissipation section with a plurality of side heat dissipation holes, in such a way that air is capable of entering said power supply from said output end to form heat convection together with said plurality of upper heat dissipation holes, said plurality of lower heat dissipation holes, said plurality of side heat dissipation holes and said plurality of front heat dissipation holes, so as to form a heat dissipation effect with respect to said power supply.

2. The power supply module with enhanced heat dissipation effect according to claim 1, wherein each of said side plates is further composed of an upper side plate connected to said top plate and a lower side plate connected to said bottom plate, as well as said plurality of side heat dissipation holes are distributed over said upper side plate and said lower side plate.

3. The power supply module with enhanced heat dissipation effect according to claim 1, wherein said input end further includes an electrical connector to be electrically coupled to said external power source.

4. The power supply module with enhanced heat dissipation effect according to claim 1, wherein said input end is further provided with a handgrip to be grasped for facilitating a swap of said power supply with respect to said rack.

5. The power supply module with enhanced heat dissipation effect according to claim 1, wherein said power supply further includes a heat dissipation fan provided in said main body portion for introducing said air from said output end and guiding said air toward said heat dissipation section.
